(19) United States
(12) Patent Application Publication
(10) Pub. No.: US 2026/0300581 A1
(43) Pub. Date: Oct. 1, 2026

(54) Reinforcement Learning for Optimized Routing in CAD Environments

(71) Applicant: Hexagon Technology Center GmbH, Heerbrugg (CH)

(72) Inventors: Suman Babu Naramsetty, Hyderabad (IN); Vamsi Krishna Dukkipati, Hyderabad (IN); Kavya M. Tiruveedhula, Guntur (IN); Sai Jyothi Gaddam, Kurichedu, Prakasam District (IN)

(21) Appl. No.: 19/096,003

(22) Filed: Mar. 31, 2025

(51) Int. Cl. G06F 30/27; G06F 30/18

(52) U.S. Cl. CPC G06F 30/27; G06F 30/18

(57) ABSTRACT

A CAD system includes a reinforcement learning (RL) routing engine that can be used to route building components by establishing a three-dimensional grid of cuboids to represent a routing space, identifying obstacles within the routing space, updating the three-dimensional grid of cuboids to indicate each cuboid that includes an obstacle, and executing a reinforcement learning routing engine on the updated three-dimensional grid of cuboids to determine an optimal route from a predetermined start location to a predetermined end location through the routing space represented by the updated three-dimensional grid of cuboids in accordance with a predetermined reward function. Certain embodiments use a combination of value-based and policy-based reinforcement learning to find an optimized routing solution based on a selected reward function. It also can adapt in real-time to complex and changing layouts, allowing engineers to focus on higher-level tasks while ensuring the system continuously produces optimized routing solutions.

### CROSS-REFERENCE TO RELATED APPLICATION(S)

None.

### FIELD OF THE INVENTION

The invention generally relates to computer-aided design (CAD) systems and, more particularly, to optimized routing of building components such as pipe, conduit, ductwork, electrical wire, communication cable, and cable tray networks in CAD systems using reinforcement learning.

### BACKGROUND OF THE INVENTION

Development, construction, and management of large-scale capital projects, such as power plants (e.g., a coal or gas fueled power generation facility), ships (e.g., military ships, cruise ships, or cargo ships), skyscrapers, and off-shore oil platforms, requires coordination of processes and data on a massive scale. In response to this need, those skilled in the art have developed comprehensive computer-aided design (CAD) systems (e.g., Hexagon/Intergraph SPOOLGEN®, SMARTPLANT® and SMART® 3D systems) that are specially configured for the rigors of such large capital projects. Such 3D design programs are typically used by engineers as a tool to facilitate their engineering work in designing, or modifying an existing design for, a capital project. Among other things, this type of design program can be implemented as a broad application suite that manages most or all phases of a large-scale capital project, from initial conception, to design, construction, handover, maintenance, management, and decommissioning.

In traditional CAD systems, the process of routing such things as pipe, conduit, ductwork, electrical wire, communication cable, and cable tray networks is challenging, especially when faced with intricate layouts and rapidly changing project demands. While existing tools offer limited automation and basic collision detection, they often require significant manual adjustments, resulting in inefficiencies, errors, and prolonged design cycles. This manual intervention hinders optimal outcomes, forcing engineers to devote extensive time to ensuring that designs are both accurate and practical.

### SUMMARY OF VARIOUS EMBODIMENTS

In accordance with one embodiment of the invention, a system, method, and computer program product for automated routing of building components performs processes including establishing a three-dimensional grid of cuboids to represent a routing space, identifying obstacles within the routing space, updating the three-dimensional grid of cuboids to indicate each cuboid that includes an obstacle, and executing a reinforcement learning routing engine on the updated three-dimensional grid of cuboids to determine an optimal route from a predetermined start location to a predetermined end location through the routing space represented by the updated three-dimensional grid of cuboids in accordance with a predetermined reward function.

In various alternative embodiments, each cuboid that includes an obstacle may be characterized as being at least one of fully filled or partially filled. The reinforcement learning routing engine may determine the optimal route by implementing a value iteration phase followed by a policy iteration phase, wherein in the value iteration phase, each cuboid may be assigned a value through iterative value-based reinforcement learning in accordance with a value function, and, in the policy iteration phase, cuboid values may be updated through iterative policy-based reinforcement learning. The policy iteration phase may update at least one of the value function or the reward function. The reinforcement learning routing engine may indicate a routing direction or action for each cuboid based on the cuboid values, e.g., at least one of up, down, left, right, forward, or backward, and optionally allowing for diagonal directions.

Additional embodiments may be disclosed and claimed.

### BRIEF DESCRIPTION OF THE DRAWINGS

Those skilled in the art should more fully appreciate advantages of various embodiments of the invention from the following “Description of Illustrative Embodiments,” discussed with reference to the drawings summarized immediately below.

FIG. 1 is a schematic diagram of a computer system that can be used to implement aspects of a CAD system in accordance with various embodiments.

FIG. 2 is a schematic diagram showing an example of a CAD system model for a plant including various pipe networks.

FIG. 3 is a logic flow diagram for routing building components, in accordance with certain embodiments.

FIG. 4 is a schematic diagram showing obstacles within cuboids in a 3D maze representation, in accordance with various embodiments.

FIG. 5 is a schematic diagram showing how the 3D maze representation is essentially a model of the environment in which each cuboid represents a cell and the 3D maze representation effectively defines edges and walls between adjacent cells based on the presence of obstacles, in accordance with various embodiments.

FIG. 6 is a schematic diagram showing cuboid state values initialized to zero, in accordance with various embodiments.

FIG. 7 is a schematic diagram showing cuboid state values updated in accordance with a value function of iterative value-based reinforcement learning, in accordance with various embodiments.

FIG. 8 is a schematic diagram showing routing directions or actions for each cuboid based on the cuboid state values of the 3D maze representation, in accordance with various embodiments.

FIG. 9 is a schematic diagram showing that an optimal path has been found from the start point to the end point through the maze of FIG. 5, in accordance with various embodiments.

FIG. 10 is a schematic diagram showing execution of the optimal path routing applied to the scenario of FIG. 4 with the policy extracted in the CAD software, in accordance with certain embodiments.

It should be noted that the foregoing figures and the elements depicted therein are not necessarily drawn to consistent scale or to any scale. Unless the context otherwise suggests, like elements are indicated by like numerals. The drawings are primarily for illustrative purposes and are not intended to limit the scope of the inventive subject matter described herein.

### DESCRIPTION OF ILLUSTRATIVE EMBODIMENTS

In certain embodiments, a CAD system includes a reinforcement learning (RL) routing engine that can be used to route building components such as pipe, conduit, ductwork, electrical wire, communication cable, and cable tray networks. As known in the art, reinforcement learning (RL) is a type of machine learning in which the system learns to make decisions through trial and error by interacting with an environment and receiving feedback in the form of rewards or penalties, with the goal of maximizing cumulative rewards over time. RL problems are often characterized as Markov Decision Processes (MDPs), where the current state and action determine the next state and reward. Certain embodiments use a combination of value-based and policy-based reinforcement learning to find an optimized routing solution based on a selected reward function. Different reward functions can produce different outcomes optimized for different goals. For purposes of this disclosure and the claims, the term “building” is meant to include anything that is, was, will be, or is designed to be built and can include buildings (e.g., skyscrapers, office buildings, apartment buildings, manufacturing facilities, warehouses, sports stadiums, etc.), power plants (e.g., power plants that generate electricity from coal, gas, etc.), vehicles (e.g., ships, airplanes, trucks, cars, boats, trains, subway systems, etc.), oil drilling platforms, etc. The disclosed solution addresses limitations discussed in the background by automating and optimizing the routing process, improving design accuracy and efficiency. It also can adapt in real-time to complex and changing layouts, allowing engineers to focus on higher-level tasks while ensuring the system continuously produces optimized routing solutions.

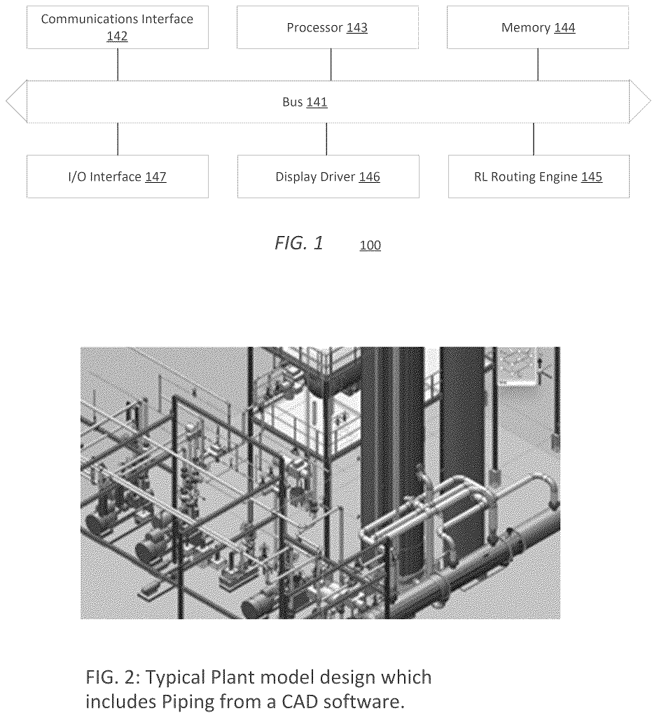

FIG. 1 is a schematic diagram of a computer system 100 that can be used to implement aspects of a CAD system in accordance with various embodiments. The computer system 100 includes several physical and/or logical modules in communication over a communications bus 141. It should be noted that CAD systems can include multiple computer systems that interoperate to perform CAD system functions. The term “bus” is used herein broadly to include any mechanism used to couple computer components.

The modules may include a communications interface module 142 communicatively coupled to one or more communication networks and configured to send and receive data over the network. For example, the communications interface 142 may send CAD drawings to, and/or receive CAD drawings from, a remote computer or database coupled to the network. Alternatively, or in addition, the communications interface 142 may send computer executable instructions to, and/or receive computer executable instructions from, a remote computer or database coupled to the network. Alternatively, or in addition, the communications interface 142 may receive operator input from, and/or display menus and CAD drawings to, an operator working on a remote terminal.

The modules also may include a processor module 143 including at least one computer processor, such as a microprocessor, coupled to a computer memory module 144 including at least one computer memory used to store computer program instructions and data used by any of various computer programs executed by the at least one computer processor and other modules.

The modules also may include a display driver module 146 configured to communicate with a display device to cause the display device to display a CAD drawing (e.g., via a graphical user interface), to name but a few examples. The display driver 146 also may be configured to receive, from a display device, input from a CAD system operator, for example, when the display device includes a touch screen.

The modules also may include an input/output interface module 147 configured to interface with any of various input/output devices (e.g., a keyboard, a mouse, a camera, an external computer memory device, etc.) to send and receive data, e.g., user inputs and related system outputs.

The modules also may include a reinforcement learning (RL) routing engine 145 (which may be implemented in whole or in part by the processor module 143) configured to use reinforcement learning for routing of capital project networks such as pipe, conduit, ductwork, electrical wire, communication cable, and cable tray networks, as described herein.

Various aspects of the invention are described herein with reference to routing of pipe networks, although it should be noted that embodiments can apply to routing of other components such as conduit, ductwork, electrical wire, communication cable, and cable tray components.

FIG. 2 is a schematic diagram showing an example of a CAD system model for a plant including various pipe networks. As shown, pipe networks can be extremely complex and can require routing relative to various other environmental elements such as around, along, or through walls, floors, ceilings and other environmental elements.

Therefore, certain embodiments, transform complex 3D spatial data into a navigable 3D maze environment, which enables a more intelligent and dynamic approach to routing. Traditional CAD tools generally depend on static inputs or predefined rules, which limit their adaptability. In contrast, the described solution organizes the space between selected equipment or points into a grid of cuboids, dividing the 3D environment into m*n*o units along the three axes. This 3D maze representation allows the system to convert obstacles—such as equipment or existing piping systems—into walls and edges within the 3D maze representation, accurately representing the 3D CAD spatial data. Then, reinforcement learning including a value iteration and a policy iteration is applied to the 3D maze representation to produce an optimized route output that avoids obstacles and adheres to process constraints. The system autonomously navigates through obstacles and adapts to design changes in real time, thereby optimizing the routing process. The algorithm learns optimal routing strategies through trial and error, iteratively refining its policy based on customized rewards that prioritize efficiency. The system may support different types of reward functions, e.g., minimizing pipe length, reducing turns, favoring affinity zones like pipe racks/trays, etc. It is expected that this innovative conversion of 3D spatial data into a maze-like framework, combined with the application of RL principles to dynamically adapt and optimize, will represent a significant advancement in routing technology compared to static routing solutions by flexibly adjusting to changing project requirements and producing optimized routing paths with minimal manual intervention.

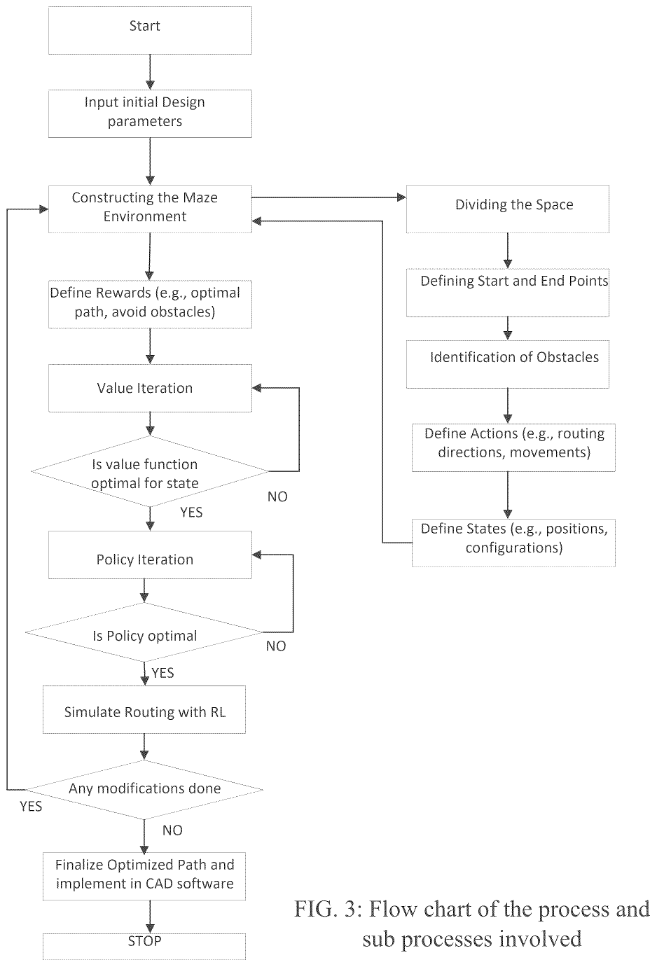

FIG. 3 is a logic flow diagram for routing building components, in accordance with certain embodiments.

First, the system receives initial design parameters. Such design parameters can include, for example, information on the type of components to be routed (e.g., water pipe, gas pipe, electrical conduit, etc.), constraints on the components to be routed (e.g., any restrictions or requirements on the placement of components), the types of components that are available (e.g., pipes, fittings, valves, flanges, pumps, and other equipment), and constraints for the components (e.g., material, outside diameter, inside diameter, corner radius, etc.).

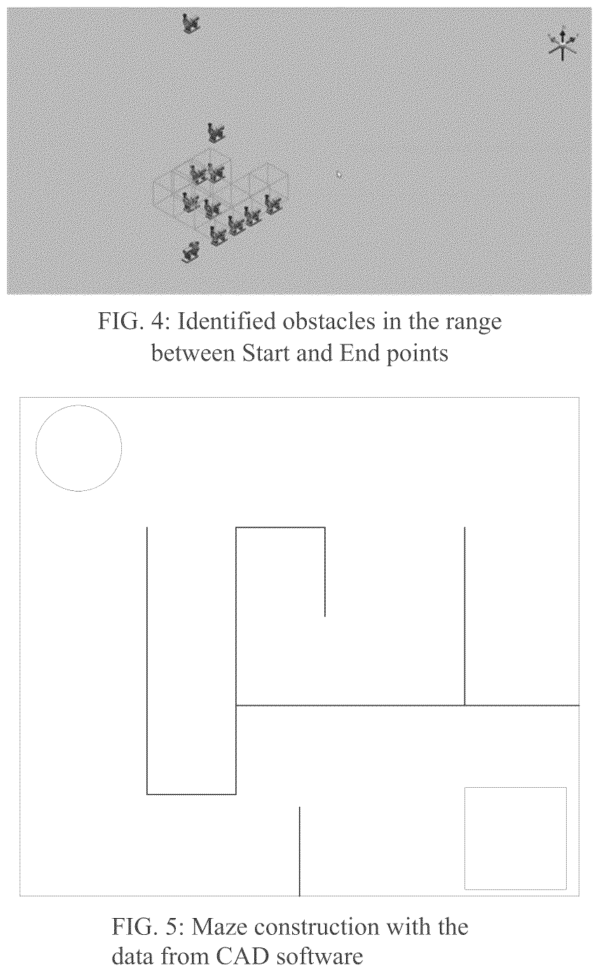

The system also constructs a 3D maze representation of the routing environment, which, in this exemplary embodiment, involves dividing the space into m*n*o cuboids to serve as the basic units for constructing the maze-like environment. Here, m, n, and o represent the number of cuboids constructed across the x, y, and z axes, respectively. This division allows for a granular representation of the space, facilitating the creation of a detailed maze environment for pipe routing optimization. It should be noted that the number and/or sizes of the cuboids can be configured for any desired level of granularity, which, for example, can depend on the start/end points, can be adapted at runtime (e.g., on a learning basis), and can be different for different routing iterations. As represented schematically in FIG. 4, the system also identifies obstacles within the space based on CAD data (e.g., walls, floor, ceiling, other pipes, other equipment, etc.) and updates the 3D maze representation to include, for each cuboid, whether the cuboid space is completely or partially filled with other objects to more accurately construct the 3D maze environment. For example, each cuboid can be characterized using a binary characterization (e.g., empty vs. completely full), a trinary characterization (e.g., empty vs. completely full vs. partially full), or a more granular characterization (e.g., dividing a cuboid into small cuboids or other partitions and characterizing each of the partitions). In this regard, cuboid sizes may be adjusted to more accurately model obstacles within the space (e.g., reducing the sizes of cuboids to more accurately reflect the locations of obstacles within the space). Ultimately, as represented schematically in FIG. 5, the 3D maze representation is essentially a model of the environment in which each cuboid represents a cell and the 3D maze representation effectively defines edges and walls between adjacent cells based on the presence of obstacles, thereby creating a navigable space for pipe routing from a start point (e.g., the circle in the upper lefthand corner) to an end point (e.g., the square in the lower righthand corner). For convenience, only a 2D representation is shown in FIG. 5, although it should be clear how the maze can be extended to three dimensions, e.g., by schematically stacking a plurality of 2D mazes of the type shown in FIG. 5 and allowing movement “vertically” between the stacked mazes.

The 3D maze representation as well as the start and end points for the pipes (which represent the locations between which the pipe routing needs to be optimized) are provided to the RL routing engine 145. The RL routing engine 145 learns the optimal policy for navigating the maze through trial and error based on a selected reward function. In certain embodiments, the RL routing engine 145 learns the optimal policy in two phases, namely a value iteration phase and a policy iteration phase.

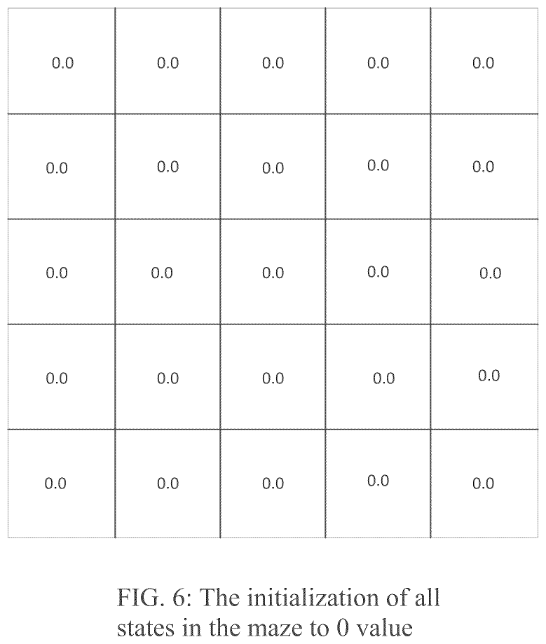

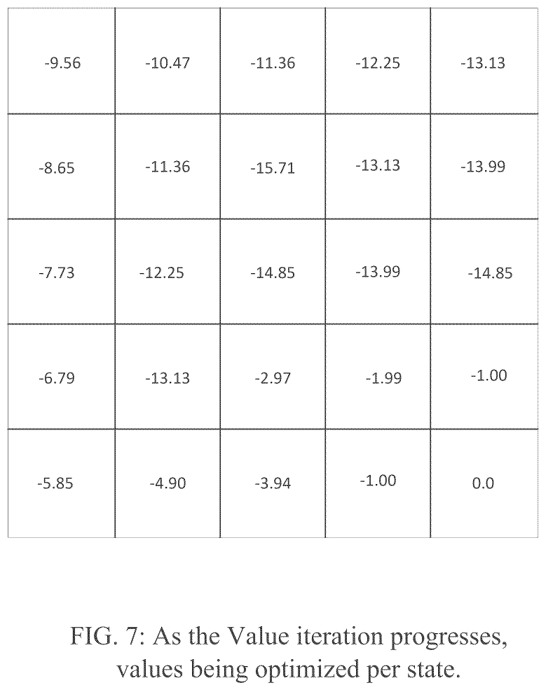

In the value iteration phase, the RL routing engine 145 iteratively learns and updates a value function for each cuboid that estimates the expected cumulative reward from each state or state-action pair. Here, the value of each state (cuboid) may be initialized to zero, as represented schematically in FIG. 6, and then updated through trial and error in accordance with the selected reward function, as represented schematically in FIG. 7, until the value function is optimal for each state, where the reward function can customize rewards within the RL algorithm to prioritize certain paths over others (e.g., a reward function may provide higher rewards for paths with fewer turns or for passages through affinity zones like pipe racks, incentivizing the algorithm to learn optimal routing strategies based on these criteria).

In the policy iteration phase, the RL routing engine 145 iteratively improves the policy by evaluating and improving the value function until the policy is optimal. By considering the rewards associated with each action and the expected future rewards from subsequent states, the algorithm learns the optimal policy for navigating the maze and to thereby simulate routing with reinforcement learning in accordance with the designated reward function (e.g., e.g., minimizing pipe length, reducing turns, favoring affinity zones like pipe racks/trays, etc.). Furthermore, each cuboid can modify the reward function dynamically based on path updates, e.g., where each cuboid's state (e.g., distance, constraint, or obstacle) influences the reward function dynamically such as to allow continuous path adjustments that accommodate design modifications in real time. This spatially aware reward approach within the cuboid maze enables RL system to respond more granularly to design constraints, unlike a general Q-learning model that lacks spatially embedded constraints.

In essence, the array represented in FIG. 7 can be viewed as a numerical value representation of the maze shown in FIG. 5, e.g., by imagining the array of FIG. 7 overlayed on the maze of FIG. 5 and the value of each cuboid representing the relative reward for moving from a given cuboid to an adjacent cuboid. For example, beginning at the start point in the upper lefthand corner (i.e., the cuboid having value −9.56), the outcome of the value iteration favors moving down to the cuboid having value −8.65 rather than moving right to the cuboid having value −10.47, then favors moving down to the cuboid having value −7.73 rather than moving right to the cuboid having value −11.36, and so on. The values in the maze can be updated during the policy iteration to reflect the goals of the reward function, e.g., minimize turns, etc.

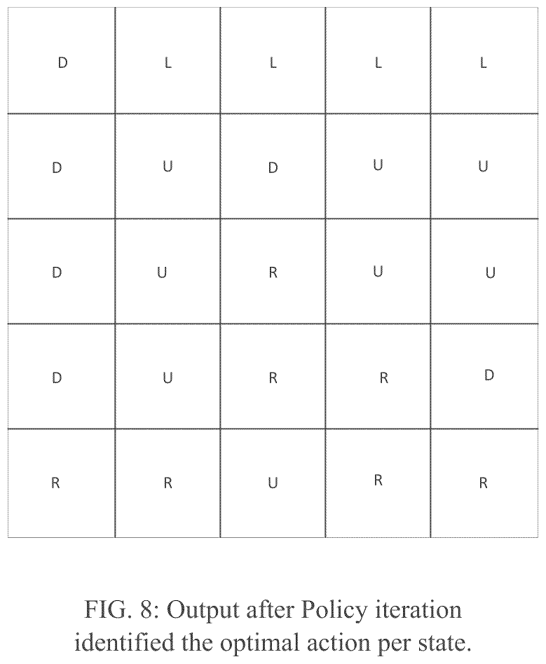

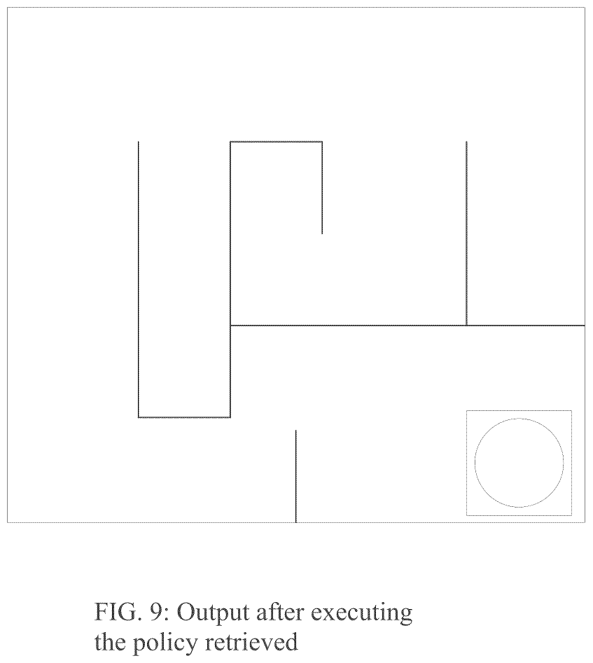

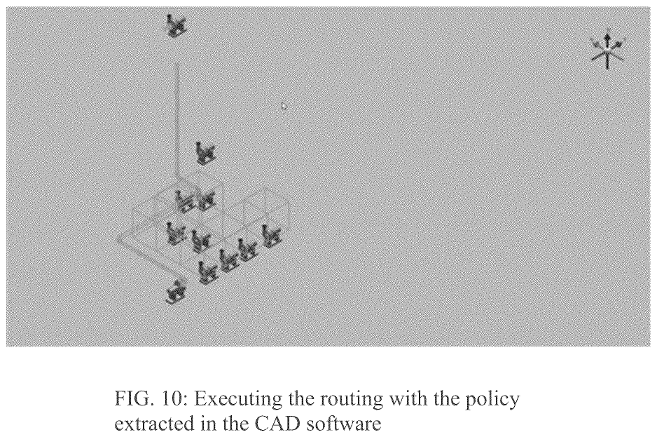

Ultimately, the RL routing engine 145 produces an optimal policy consisting of the directions or actions that the system must take at each cuboid to reach the end point from the start point in accordance with the selected goal. For example, as depicted schematically in FIG. 8, these actions could include moving up (“U), down (“D”), left (“L”), right (“R”), forward, or backward, depending on the specific layout of the maze and the obstacles present. Embodiments could allow for moving in diagonal directions, in which case separate values could be produced for moving in diagonal directions (e.g., a given cuboid could have a value for purposes evaluating movement in x, y, z axes and a separate value for evaluating diagonal movement. In essence, the optimal policy provides a set of guidelines or rules that guide the system through the maze, ensuring that it navigates efficiently towards the destination while adhering to certain criteria such as minimum pipe length, minimizing turns, or prioritizing passages through affinity zones like pipe racks. Overall, the output of the RL routing engine 145 guides the pipe routing system in making decisions at each step of the routing process, ultimately leading to the generation of an optimized pipe route between the start and end points within the maze environment. In the example shown in FIG. 8, the optimized pipe route between the start and end points is determined to be moving four steps down from the starting point, then moving two steps right, then moving one step up, then moving two steps right, and finally moving one step down to terminate at the end point. Based on the values shown in FIG. 7, an alternate path with the same overall score could have included moving four steps down from the starting point, then moving two steps right, then moving one step up, then moving one step right, then moving one step down, and finally moving one step right to terminate at the end point, although this alternate path would involve five turns whereas the path shown in FIG. 8 only involves four turns. Therefore, if the reward function had been minimizing the number of turns, then the policy iteration may have favored the path shown in FIG. 8 with four turns over the path with five turns. However, if the reward function had been something else, then perhaps the policy iteration may have favored the path with five turns over the path with four turns and therefore the policy iteration could have changed the array values so that the five-turn path has a lower overall score than the four-turn path. It is interesting to note that FIG. 8 includes actions for all of the cuboids such that the reinforcement learning engine can evaluate all possible paths from the start point to the end point. For example, if the reinforcement learning engine selects a path that somehow reaches the upper righthand corner, then the reinforcement learning engine is told to go to the left from that cuboid, and if the reinforcement learning engine somehow selects a path that reaches the center cuboid, then the reinforcement learning engine is told to go right from that cuboid, and each successive cuboid provide a direction that will return the reinforcement learning engine to the starting point from where it can find a path to the end point. Also, as mentioned above, embodiments could allow for moving in diagonal directions, e.g., moving from the cuboid with value −6.79 diagonally to the cuboid with value −4.90 rather than moving down from the cuboid with value −6.79 to the cuboid with value −5.85 and then moving right to the cuboid with value −4.90. In any case, FIG. 9 schematically shows that an optimal path has been found from the start point to the end point through the maze of FIG. 5 to effectively demonstrate the conversion of the optimal path into a 3D output for adaptive dynamic routing. FIG. 10 is a schematic diagram showing execution of the optimal path routing applied to the scenario of FIG. 4 with the policy extracted in the CAD software, in accordance with certain embodiments.

It should be noted that the system can react to changes to the environment (e.g., design changes or as-built differences) by repeating the process to determine the new optimal routing policy. Each repetition can incorporate real-time, modular updates to obstacles and paths within the cuboid structure. This ensures that the RL-based routing adapts to new constraints immediately, unlike approaches that define routes statically at the start. Each repetition can leverage the 3D maze representation from the prior iteration, e.g., by allowing each newly created path to transform occupied cuboids into obstacles in real-time to help streamline multi-route processing (e.g., routing multiple building components across multiple iterations) without requiring separate obstacle-defining steps. This approach allows more efficient route prioritization and adaptability to complex, changing layouts, as opposed to starting from scratch for each of a number of successive subsequent routes.

It also should be noted that the RL routing engine 145 can be trained through the same process using actual and/or simulated training data to produce routing models for each of the reward functions or routing goals. Such models can be applied during subsequent routing processes, e.g., to produce or update state values during the value iteration phase and/or the policy iteration phase. Thus, for example, the RL routing engine 145 may be trained, and then the trained RL routing engine 145 may be applied to a subsequent routing process. Human input may be used as feedback during the training process to further hone the routing “skills” of the RL routing engine 145 in making routing decisions.

The described routing system has practical applications that can transform design workflows in CAD environments by automating the optimization of routing paths while dynamically adjusting to design constraints in real time and significantly reducing the manual effort required for optimal routing. By intelligently navigating complex 3D spaces and optimizing routes in real time, it enhances productivity, improves design quality, and accelerates project timelines. The system's ability to adapt in real time to changing project constraints can eliminate the need for manual rerouting, minimizing costly errors and rework. Its seamless integration with existing CAD platforms enables engineers to achieve higher levels of precision, efficiency, and innovation, making it a valuable tool for modern engineering projects.

More specifically, unlike some known solutions that rely on manual optimization methods, the described embodiments offer automated optimization using reinforcement learning (RL) algorithms, reducing the need for manual intervention, and streamlining design workflows. Embodiments also dynamically adapt to changing project requirements, ensuring that routes remain optimized throughout the design process. This flexibility allows for seamless adjustments and minimizes the need for redesign. By leveraging RL algorithms, embodiments can explore a broader design space, uncovering innovative solutions and generating pipe routes that minimize clashes and adhere to design constraints more effectively than traditional methods. The integration of RL with CAD software enhances design quality by delivering optimized routes that meet project specifications and industry standards with unprecedented efficiency. With automated optimization and dynamic adaptation capabilities, embodiments can enhance productivity in system engineering by reducing iteration time and increasing design efficiency. The fusion of machine learning and design engineering represents a groundbreaking advancement in pipe routing technology, enabling intelligent and adaptive solutions that surpass the capabilities of traditional CAD software alone.

The following are some additional benefits and distinctions of various described embodiments over other solutions.

Unlike a reinforcement learning model with multiple agents and a reward function based on cost and complexity values that does not address spatial subdivision into cuboids nor the structured approach of defining and embedding physical constraints, the described embodiments focus on creating a maze-like 3D environment using cuboids that spatially partition the CAD model, which offers a more granular control over obstacles, pathfinding, and system behavior. This cuboid-based structure allows the system to incorporate dynamic constraints directly within the environment before feeding it to an RL algorithm, offering higher flexibility and avoiding the need for multiple agents per route.

Unlike solutions that use a standard graph search, the described embodiments instead construct a spatial maze using cuboids, providing a more adaptable setup for complex routing. The maze allows for dynamic routing adjustments, considering individual cuboid states (e.g., open, partial, or full) and continuous path optimization, which is absent in standard graph-based searches. This flexibility ensures that the described method can adapt to changing design needs without reinitializing the entire routing model.

Rather than using pre-existing system requirements to generate solutions while preserving certain pre-designed elements, the described embodiments diverge by embedding these spatial constraints into the cuboid-based maze, where each cuboid represents a spatial requirement, obstacle, or pathway. This maze construction approach offers a more flexible and adaptable routing environment, allowing real-time reconfigurations that react to updated constraints or fixed elements without disrupting the overall environment. This enables the system to handle evolving project requirements more natively than merely working within fixed pre-designed parameters.

Rather than using a 3D CNN model that processes a coarse geometry representation to estimate route complexity, cost, and maintainability, the described embodiments achieve granular spatial control by dividing the CAD space into small cuboid partitions, which provides detailed, accurate feedback to the reinforcement learning model. Instead of relying on coarse geometry, the described embodiments ensure that each route is optimized based on real, spatially subdivided data, which is more precise and flexible than a coarse CNN-based representation. This direct spatial approach enhances the described solution's effectiveness in dynamic and real-time environments by facilitating direct interaction with each spatial segment.

The described embodiments do not rely on a single, static 3D model of the layout space but instead use Reinforcement Learning (RL) to adaptively route components within the CAD environment. Unlike fixed design space, they system can dynamically adjust routing paths based on real-time project updates, offering greater flexibility and responsiveness to changing layout requirements.

The described embodiments do not require STL files or simplification of device geometry but instead create a maze-like environment within CAD, dividing space into cuboids, which the RL algorithms use to navigate efficiently through complex spaces. This approach can eliminate the need for pre-processing model geometry, allowing for greater detail and accuracy in real-time routing. Because the described embodiments identify obstacles within the CAD model by analyzing cuboid-based navigation spaces, the system supports dynamic occupancy assessment, enabling the RL-driven routing to adapt as layout changes occur, unlike static, pre-defined occupancy based on STL files.

In contrast to static grid, the described embodiments construct a maze-like environment with cuboid cells that RL algorithms use for dynamic navigation and obstacle avoidance. This structure provides fine-grained control over routing paths, supporting adaptability and real-time path recalibration that the fixed grid approach.

Unlike systems that rely on external schematic diagrams or manual connectivity mapping, the RL algorithms within CAD autonomously learn and adjust routing paths. This built-in intelligence removes the need for external analysis or pre-configured connectivity, enhancing real-time adaptability and design efficiency. The described embodiments uniquely leverage Reinforcement Learning (RL) methods, such as Value Iteration and Policy Iteration, to continuously learn optimal routing paths. Unlike static optimization methods, RL in the described system can actively explore new paths and can recalibrate routing based on evolving project requirements, making it more adaptable to design changes.

The described embodiments can perform optimization and visualization directly within the CAD environment in real time, eliminating the need for external software like SolidWorks for post-processed route modelling. This in-CAD optimization provides an integrated, efficient process distinct from the post-optimization modelling approach.

The described embodiments avoid static grading systems by utilizing custom reward structures within RL to guide pathfinding. For instance, RL algorithms in the system can prioritize paths with fewer turns or paths passing through affinity zones, adapting dynamically to routing requirements. This reward-based navigation offers a flexible, intelligent approach that surpasses fixed Euclidean distance grading.

Rather than using a static search algorithm to identify the route, based on predefined rules and constraints, the described embodiments us reinforcement learning (RL) to dynamically reoptimize and adapt the routing based on continuous feedback from the environment.

Rather than using 3D CAD to divide the space for routing without real-time learning or optimization of the pathfinding process, the described embodiments go beyond static pathfinding by using reinforcement learning, which allows the system to adapt to obstacles dynamically and continuously optimize the routing based on changing project needs.

More generally, the described embodiments seek to enhance design efficiency by using reinforcement learning (RL) to determine optimal routes (e.g., for piping and wiring) early in the design stage using a unique spatial partitioning method, dividing the CAD space into maze-like cuboids that provide detailed, interactive constraints. This allows for more accurate path optimization directly within the CAD environment, which offers flexibility that RL alone may lack without structured spatial division.

Unlike systems that define a 2D or 3D virtual environment with domain information as text, including start and endpoints, obstacles, and pathway options, the described embodiments go beyond this by embedding these elements within cuboid-based spatial subdivisions, allowing each cuboid to represent specific constraints (obstacle, start, endpoint, etc.) directly within the CAD model, facilitating dynamic route adjustment and more precise spatial management.

Unlike systems in which the size and position of obstacles are described using starting points and directional lengths in 3D, the described embodiments embed obstacles within cuboids in a spatial maze, allowing obstacles to be directly manipulated within a fine-grained environment. This cuboid structure enables the RL model to interact with obstacles dynamically, providing more adaptability and spatial precision than fixed-point obstacle definitions.

Various embodiments of the invention may be implemented at least in part in any conventional computer programming language. For example, some embodiments may be implemented in a procedural programming language (e.g., “C”), or in an object-oriented programming language (e.g., “C++”). Other embodiments of the invention may be implemented as a pre-configured, stand-alone hardware element and/or as preprogrammed hardware elements (e.g., application specific integrated circuits, FPGAs, and digital signal processors), or other related components.

In alternative embodiments, the disclosed apparatus and methods (e.g., as in any flow charts or logic flows described above) may be implemented as a computer program product for use with a computer system. Such implementation may include a series of computer instructions fixed on a tangible, non-transitory medium, such as a computer readable medium (e.g., a diskette, CD-ROM, ROM, or fixed disk). The series of computer instructions can embody all or part of the functionality previously described herein with respect to the system.

Those skilled in the art should appreciate that such computer instructions can be written in a number of programming languages for use with many computer architectures or operating systems. Furthermore, such instructions may be stored in any memory device, such as a tangible, non-transitory semiconductor, magnetic, optical or other memory device, and may be transmitted using any communications technology, such as optical, infrared, RF/microwave, or other transmission technologies over any appropriate medium, e.g., wired (e.g., wire, coaxial cable, fiber optic cable, etc.) or wireless (e.g., through air or space).

Among other ways, such a computer program product may be distributed as a removable medium with accompanying printed or electronic documentation (e.g., shrink wrapped software), preloaded with a computer system (e.g., on system ROM or fixed disk), or distributed from a server or electronic bulletin board over the network (e.g., the Internet or World Wide Web). In fact, some embodiments may be implemented in a software-as-a-service model (“SAAS”) or cloud computing model. Of course, some embodiments of the invention may be implemented as a combination of both software (e.g., a computer program product) and hardware. Still other embodiments of the invention are implemented as entirely hardware, or entirely software.

Computer program logic implementing all or part of the functionality previously described herein may be executed at different times on a single processor (e.g., concurrently) or may be executed at the same or different times on multiple processors and may run under a single operating system process/thread or under different operating system processes/threads. Thus, the term “computer process” refers generally to the execution of a set of computer program instructions regardless of whether different computer processes are executed on the same or different processors and regardless of whether different computer processes run under the same operating system process/thread or different operating system processes/threads. Software systems may be implemented using various architectures such as a monolithic architecture or a microservices architecture.

It should be noted that the term “computer” (e.g., in the context of the computer system 100) may be used herein to describe devices or systems that may be used in certain embodiments of the present invention and should not be construed to limit the present invention to any particular type of device or system unless the context otherwise requires. Thus, a computer may include, without limitation, a server, a computer (including desktop, laptop, tablet, portable, wearable, mainframe, etc.), a cloud computing platform, an appliance, or other type of device or system. Such devices or systems typically include one or more network interfaces for communicating over a communication network and at least one processor (e.g., a microprocessor with memory and other peripherals and/or application-specific hardware) configured accordingly to perform device or system functions. Communication networks generally may include public and/or private networks; may include local-area, wide-area, metropolitan-area, storage, and/or other types of networks; and may employ communication technologies including, but in no way limited to, analog technologies, digital technologies, optical technologies, wireless technologies (e.g., Bluetooth, WiFi, cellular, etc.), networking technologies, and internetworking technologies.

It should also be noted that devices and systems may use communication protocols and messages (e.g., messages created, transmitted, received, stored, and/or processed by the device or system), and such messages may be conveyed by a communication network or medium. Unless the context otherwise requires, the present invention should not be construed as being limited to any particular communication message type, communication message format, or communication protocol. Thus, a communication message generally may include, without limitation, a frame, packet, datagram, user datagram, cell, or other type of communication message. Unless the context requires otherwise, references to specific communication protocols are exemplary, and it should be understood that alternative embodiments may, as appropriate, employ variations of such communication protocols (e.g., modifications or extensions of the protocol that may be made from time-to-time) or other protocols either known or developed in the future.

It should also be noted that logic flows may be described herein to demonstrate various aspects of the invention, and should not be construed to limit the present invention to any particular logic flow or logic implementation. The described logic may be partitioned into different logic blocks (e.g., programs, modules, functions, or subroutines) without changing the overall results or otherwise departing from the true scope of the invention. Often times, logic elements may be added, modified, omitted, performed in a different order, or implemented using different logic constructs (e.g., logic gates, looping primitives, conditional logic, and other logic constructs) without changing the overall results or otherwise departing from the true scope of the invention.

The present invention may be embodied in many different forms, including, but in no way limited to, computer program logic for use with a processor (e.g., a microprocessor, microcontroller, digital signal processor, or general purpose computer), programmable logic for use with a programmable logic device (e.g., a Field Programmable Gate Array (FPGA) or other PLD), discrete components, integrated circuitry (e.g., an Application Specific Integrated Circuit (ASIC)), or any other means including any combination thereof. Computer program logic implementing some or all of the described functionality is typically implemented as a set of computer program instructions that is converted into a computer executable form, stored as such in a computer readable medium, and executed by one or more processors optionally under the control of an operating system. Hardware-based logic implementing some or all of the described functionality may be implemented using one or more appropriately configured FPGAs or other programmable logic devices.

Computer program logic implementing all or part of the functionality previously described herein may be embodied in various forms, including, but in no way limited to, a source code form, a computer executable form, and various intermediate forms (e.g., forms generated by an assembler, compiler, linker, or locator). Source code may include a series of computer program instructions implemented in any of various programming languages (e.g., an object code, an assembly language, or a high-level language such as Fortran, C, C++, JAVA, or HTML) for use with various operating systems or operating environments. The source code may define and use various data structures and communication messages. The source code may be in a computer executable form (e.g., via an interpreter), or the source code may be converted (e.g., via a translator, assembler, or compiler) into a computer executable form.

Computer program logic implementing all or part of the functionality previously described herein may be executed at different times on a single processor (e.g., concurrently) or may be executed at the same or different times on multiple processors and may run under a single operating system process/thread or under different operating system processes/threads. Thus, the term “computer process” refers generally to the execution of a set of computer program instructions regardless of whether different computer processes are executed on the same or different processors and regardless of whether different computer processes run under the same operating system process/thread or different operating system processes/threads.

The computer program may be fixed in any form (e.g., source code form, computer executable form, or an intermediate form) either permanently or transitorily in a tangible storage medium, such as a semiconductor memory device (e.g., a RAM, ROM, PROM, EEPROM, or Flash-Programmable RAM), a magnetic memory device (e.g., a diskette or fixed disk), an optical memory device (e.g., a CD-ROM), a PC card (e.g., PCMCIA card), or other memory device. The computer program may be fixed in any form in a signal that is transmittable to a computer using any of various communication technologies, including, but in no way limited to, analog technologies, digital technologies, optical technologies, wireless technologies (e.g., Bluetooth), networking technologies, and internetworking technologies. The computer program may be distributed in any form as a removable storage medium with accompanying printed or electronic documentation (e.g., shrink wrapped software), preloaded with a computer system (e.g., on system ROM or fixed disk), or distributed from a server or electronic bulletin board over the communication system (e.g., the Internet or World Wide Web).

Hardware logic (including programmable logic for use with a programmable logic device) implementing all or part of the functionality previously described herein may be designed using traditional manual methods, or may be designed, captured, simulated, or documented electronically using various tools, such as Computer Aided Design (CAD), a hardware description language (e.g., VHDL or AHDL), or a PLD programming language (e.g., PALASM, ABEL, or CUPL).

Programmable logic may be fixed either permanently or transitorily in a tangible storage medium, such as a semiconductor memory device (e.g., a RAM, ROM, PROM, EEPROM, or Flash-Programmable RAM), a magnetic memory device (e.g., a diskette or fixed disk), an optical memory device (e.g., a CD-ROM), or other memory device. The programmable logic may be fixed in a signal that is transmittable to a computer using any of various communication technologies, including, but in no way limited to, analog technologies, digital technologies, optical technologies, wireless technologies (e.g., Bluetooth), networking technologies, and internetworking technologies. The programmable logic may be distributed as a removable storage medium with accompanying printed or electronic documentation (e.g., shrink wrapped software), preloaded with a computer system (e.g., on system ROM or fixed disk), or distributed from a server or electronic bulletin board over the communication system (e.g., the Internet or World Wide Web). Of course, some embodiments of the invention may be implemented as a combination of both software (e.g., a computer program product) and hardware. Still other embodiments of the invention are implemented as entirely hardware, or entirely software.

While the invention has been particularly shown and described with reference to specific embodiments, it will be understood by persons of ordinary skill in the art that various changes in form and detail may be made without departing from the spirit and scope of the invention as defined by the appended clauses. While some of these embodiments have been described in the claims by process steps, an apparatus comprising a computer capable of executing the process steps is also included in the present invention. Likewise, a computer program product comprising a tangible, non-transitory computer readable medium having embodied therein computer executable instructions for executing the process steps is included in the present invention. Data signals embodying computer program instructions and/or messages received or transmitted over a communication system are also included in the present invention. Unless the context requires otherwise, the various functions and features described herein can be used in combination even if disclosed or claimed individually. Thus, for example, it is contemplated that dependent claims included below could be rewritten into multiple dependent form to depend from the base claim and an intervening claim(s).

Importantly, it should be noted that embodiments of the present invention may employ conventional components such as conventional computers (e.g., off-the-shelf PCs, mainframes, microprocessors), conventional programmable logic devices (e.g., off-the shelf FPGAs or PLDs), or conventional hardware components (e.g., off-the-shelf ASICs or discrete hardware components) which, when programmed or configured to perform the non-conventional methods described herein, produce non-conventional devices or systems. Thus, there is nothing conventional about the inventions described herein because even when embodiments are implemented using conventional components, the resulting devices and systems (e.g., the RL routing engine 145 specifically and the computer system 100 generally) are necessarily non-conventional because, absent special programming or configuration, the conventional components do not inherently perform the described non-conventional functions.

The activities described and claimed herein provide technological solutions to problems that arise squarely in the realm of technology. These solutions as a whole are not well-understood, routine, or conventional and in any case provide practical applications that transform and improve computers and computer routing systems.

While various inventive embodiments have been described and illustrated herein, those of ordinary skill in the art will readily envision a variety of other means and/or structures for performing the function and/or obtaining the results and/or one or more of the advantages described herein, and each of such variations and/or modifications is deemed to be within the scope of the inventive embodiments described herein. More generally, those skilled in the art will readily appreciate that all parameters, dimensions, materials, and configurations described herein are meant to be exemplary and that the actual parameters, dimensions, materials, and/or configurations will depend upon the specific application or applications for which the inventive teachings is/are used. Those skilled in the art will recognize, or be able to ascertain using no more than routine experimentation, many equivalents to the specific inventive embodiments described herein. It is, therefore, to be understood that the foregoing embodiments are presented by way of example only and that, within the scope of the appended claims and equivalents thereto, inventive embodiments may be practiced otherwise than as specifically described and claimed. Inventive embodiments of the present disclosure are directed to each individual feature, system, article, material, kit, and/or method described herein. In addition, any combination of two or more such features, systems, articles, materials, kits, and/or methods, if such features, systems, articles, materials, kits, and/or methods are not mutually inconsistent, is included within the inventive scope of the present disclosure.

Various inventive concepts may be embodied as one or more methods, of which examples have been provided. The acts performed as part of the method may be ordered in any suitable way. Accordingly, embodiments may be constructed in which acts are performed in an order different than illustrated, which may include performing some acts simultaneously, even though shown as sequential acts in illustrative embodiments.

All definitions, as defined and used herein, should be understood to control over dictionary definitions, definitions in documents incorporated by reference, and/or ordinary meanings of the defined terms.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B”, when used in conjunction with open-ended language such as “comprising” can refer, in one embodiment, to A only (optionally including elements other than B); in another embodiment, to B only (optionally including elements other than A); in yet another embodiment, to both A and B (optionally including other elements); etc.

As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e., “one or the other but not both”) when preceded by terms of exclusivity, such as “either,” “one of,” “only one of,” or “exactly one of.” “Consisting essentially of,” when used in the claims, shall have its ordinary meaning as used in the field of patent law.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

As used herein in the specification and in the claims, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively, as set forth in the United States Patent Office Manual of Patent Examining Procedures, Section 2111.03.

It should be noted that connecting lines with or without arrows may be used in drawings to represent communication, transfer, or other activity involving two or more entities. Connecting lines with double-ended arrows generally indicate that activity may occur in both directions (e.g., a command/request in one direction with a corresponding reply back in the other direction, or peer-to-peer communications initiated by either entity), although in some situations, activity may not necessarily occur in both directions. Connecting lines with single-ended arrows generally indicate activity exclusively or predominantly in the direction of the arrow, although it should be noted that, in certain situations, such directional activity may involve activities in the opposite direction or in both directions (e.g., a message from a sender to a receiver and an acknowledgment back from the receiver to the sender, or establishment of a connection prior to a transfer and termination of the connection following the transfer). Thus, the type of arrow used in a particular drawing to represent a particular activity is exemplary and should not be seen as limiting. Connecting lines with no arrows can indicate activity in one, the other, or both directions as the context suggests. Dashed connecting lines may be used to represent optional or ancillary activities as the context suggests.

Although the above discussion discloses various exemplary embodiments of the invention, it should be apparent that those skilled in the art can make various modifications that will achieve some of the advantages of the invention without departing from the true scope of the invention. Any references to the “invention” are intended to refer to exemplary embodiments of the invention and should not be construed to refer to all embodiments of the invention unless the context otherwise requires. The described embodiments are to be considered in all respects only as illustrative and not restrictive.

What is claimed is:

1. A system for automated routing of building components, the system comprising:
at least one processor and at least one memory containing computer program instructions which, when executed by the at least one processor, perform processes comprising:
establishing, in at least one memory, a three-dimensional grid of cuboids to represent a routing space;
identifying obstacles within the routing space;
updating the three-dimensional grid of cuboids to indicate each cuboid that includes an obstacle; and
executing a reinforcement learning routing engine on the updated three-dimensional grid of cuboids to determine an optimal route from a predetermined start location to a predetermined end location through the routing space represented by the updated three-dimensional grid of cuboids in accordance with a predetermined reward function.

2. The system of claim 1, wherein each cuboid that includes an obstacle is characterized as being at least one of fully filled or partially filled.

3. The system of claim 1, wherein the reinforcement learning routing engine determines the optimal route by implementing a value iteration phase followed by a policy iteration phase.

4. The system of claim 3, wherein:
in the value iteration phase, each cuboid is assigned a value through iterative value-based reinforcement learning in accordance with a value function; and
in the policy iteration phase, cuboid values are updated through iterative policy-based reinforcement learning.

5. The system of claim 4, wherein the policy iteration phase updates at least one of the value function or the reward function.

6. The system of claim 4, wherein the reinforcement learning routing engine indicates a routing direction or action for each cuboid based on the cuboid values.

7. The system of claim 6, wherein the routing direction or action for each cuboid includes at least one of up, down, left, right, forward, or backward.

8. A method for automated routing of building components, the method comprising:
establishing, in at least one memory, a three-dimensional grid of cuboids to represent a routing space;
identifying obstacles within the routing space;
updating the three-dimensional grid of cuboids to indicate each cuboid that includes an obstacle; and
executing a reinforcement learning routing engine on the updated three-dimensional grid of cuboids to determine an optimal route from a predetermined start location to a predetermined end location through the routing space represented by the updated three-dimensional grid of cuboids in accordance with a predetermined reward function.

9. The method of claim 8, wherein each cuboid that includes an obstacle is characterized as being at least one of fully filled or partially filled.

10. The method of claim 8, wherein the reinforcement learning routing engine determines the optimal route by implementing a value iteration phase followed by a policy iteration phase.

11. The method of claim 10, wherein:
in the value iteration phase, each cuboid is assigned a value through iterative value-based reinforcement learning in accordance with a value function; and
in the policy iteration phase, cuboid values are updated through iterative policy-based reinforcement learning.

12. The method of claim 11, wherein the policy iteration phase updates at least one of the value function or the reward function.

13. The method of claim 11, wherein the reinforcement learning routing engine indicates a routing direction or action for each cuboid based on the cuboid values.

14. The method of claim 13, wherein the routing direction or action for each cuboid includes at least one of up, down, left, right, forward, or backward.

15. A computer program product comprising at least one tangible, non-transitory computer readable medium having embodied therein computer program instructions which, when executed by at least one processor, implements a reinforcement learning (RL) routing engine that performs processes comprising:
establishing, in at least one memory, a three-dimensional grid of cuboids to represent a routing space;
identifying obstacles within the routing space;
updating the three-dimensional grid of cuboids to indicate each cuboid that includes an obstacle; and
executing a reinforcement learning routing engine on the updated three-dimensional grid of cuboids to determine an optimal route from a predetermined start location to a predetermined end location through the routing space represented by the updated three-dimensional grid of cuboids in accordance with a predetermined reward function.

16. The computer program product of claim 15, wherein each cuboid that includes an obstacle is characterized as being at least one of fully filled or partially filled.

17. The computer program product of claim 15, wherein the reinforcement learning routing engine determines the optimal route by implementing a value iteration phase followed by a policy iteration phase.

18. The computer program product of claim 17, wherein:
in the value iteration phase, each cuboid is assigned a value through iterative value-based reinforcement learning in accordance with a value function; and
in the policy iteration phase, cuboid values are updated through iterative policy-based reinforcement learning.

19. The computer program product of claim 18, wherein the policy iteration phase updates at least one of the value function or the reward function.

20. The computer program product of claim 18, wherein the reinforcement learning routing engine indicates a routing direction or action for each cuboid based on the cuboid values.

21. The computer program product of claim 20, wherein the routing direction or action for each cuboid includes at least one of up, down, left, right, forward, or backward.
